(19) United States
(12) Patent Application Publication
(10) Pub. No.: US 2026/0293532 A1
(43) Pub. Date: Sep. 24, 2026

(54) MAGNETIC MEMORY DEVICE

(71) Applicant: Kioxia Corporation, Minato-ku (JP)

(72) Inventors: Naoki AKIYAMA, Yokkaichi Mie (JP); Kenichi YOSHINO, Seongnam-si Gyeonggi-do (KR); Hyung-Woo AHN, Seongnam-si Gyeonggi-do (KR); Hyungjun CHO, Seongnam-si Gyeonggi-do (KR); Takuya SHIMANO, Seoul (KR)

(73) Assignee: Kioxia Corporation, Minato-ku (JP)

(21) Appl. No.: 19/323,785

(22) Filed: Sep. 9, 2025

(30) Foreign Application Priority Data
Mar. 21, 2025 (JP) 2025-046953

(51) Int. Cl. H10N 50/10; G11C 11/16; H10N 50/85

(52) U.S. Cl. CPC H10N 50/10; G11C 11/161; H10N 50/85

(57) ABSTRACT

According to one embodiment, a magnetic memory device includes a main body portion, an upper structure portion on the main body portion, and a sidewall insulating layer on side walls of the main body portion and upper structure portion, containing an oxide containing a predetermined element and oxygen, and having a bond dissociation energy between the predetermined element and oxygen of 500 kJ/mol or more. The upper structure portion includes a first structure portion including a predetermined material layer portion containing a predetermined material selected from Pt, Co, Ir, Mn, Ni, Au, Ta, and Ru, and a lower material layer portion on a lower layer side of the predetermined material layer portion and containing a material different from the predetermined material.

### CROSS-REFERENCE TO RELATED APPLICATIONS

This application is based upon and claims the benefit of priority from Japanese Patent Application No. 2025-046953, filed Mar. 21, 2025, the entire contents of which are incorporated herein by reference.

### FIELD

Embodiments described herein relate generally to a magnetic memory device.

### BACKGROUND

Magnetic memory devices in which plurality of magnetoresistance effect elements are integrated on a semiconductor substrate have been proposed.

### BRIEF DESCRIPTION OF THE DRAWINGS

FIG. 1 is a cross-sectional view schematically showing a configuration of a magnetic memory device according to an embodiment.

FIG. 2A is a cross-sectional view schematically showing an example of the configuration of a main body portion of a magnetoresistance effect element included in the magnetic memory device according to the embodiment.

FIG. 2B is a cross-sectional view schematically showing another example of the configuration of the main body portion of the magnetoresistance effect element included in the magnetic memory device according to the embodiment.

FIG. 3A is a cross-sectional view schematically showing a first specific example of an upper structure portion of the magnetoresistance effect element included in the magnetic memory device according to the embodiment.

FIG. 3B is a cross-sectional view schematically showing a second specific example of the upper structure portion of the magnetoresistance effect element included in the magnetic memory device according to the embodiment.

FIG. 3C is a cross-sectional view schematically showing a third specific example of the upper structure portion of the magnetoresistance effect element included in the magnetic memory device according to the embodiment.

FIG. 3D is a cross-sectional view schematically showing a fourth specific example of the upper structure portion of the magnetoresistance effect element included in the magnetic memory device according to the embodiment.

FIG. 4A is a cross-sectional view schematically showing a part of a method of manufacturing the magnetic memory device according to the embodiment.

FIG. 4B is a cross-sectional view schematically showing a part of the method of manufacturing the magnetic memory device according to the embodiment.

FIG. 4C is a cross-sectional view schematically showing a part of the method of manufacturing the magnetic memory device according to the embodiment.

FIG. 4D is a cross-sectional view schematically showing a part of the method of manufacturing the magnetic memory device according to the embodiment.

FIG. 4E is a cross-sectional view schematically showing a part of the method of manufacturing the magnetic memory device according to the embodiment.

FIG. 4F is a cross-sectional view schematically showing a part of the method of manufacturing the magnetic memory device according to the embodiment.

FIG. 4G is a cross-sectional view schematically showing a part of the method of manufacturing the magnetic memory device according to the embodiment.

FIG. 4H is a cross-sectional view schematically showing a part of the method of manufacturing the magnetic memory device according to the embodiment.

FIG. 5 is a cross-sectional view schematically showing a configuration of a modified example of the magnetic memory device according to the embodiment.

FIG. 6 is a cross-sectional view schematically showing a configuration of an application example of the magnetic memory device according to the embodiment.

### DETAILED DESCRIPTION

In general, according to one embodiment, a magnetic memory device includes a main body portion of a magnetoresistance effect element, including a first magnetic layer, a second magnetic layer, and a non-magnetic layer provided between the first magnetic layer and the second magnetic layer, an upper structure portion of the magnetoresistance effect element, stacked on the main body portion, and a sidewall insulating layer of the magnetic resistance effect element, provided on a side wall of the main body portion and on a side wall of the upper structure portion, containing an oxide containing a predetermined element and oxygen, and having a bond dissociation energy between the predetermined element and oxygen of 500 kJ/mol or more, and the upper structure portion includes a first structure portion including a predetermined material layer portion containing a predetermined material that contains an element selected from platinum (Pt), cobalt (Co), iridium (Ir), manganese (Mn), nickel (Ni), gold (Au), tantalum (Ta), and ruthenium (Ru), and a lower material layer portion provided on a lower layer side of the predetermined material layer portion and containing a material different from the predetermined material.

Embodiments will now be described with reference to the accompanying drawings.

FIG. 1 is a cross-sectional view schematically showing a configuration of a magnetic memory device according to an embodiment. Note that in the following description, an X direction, Y direction, and Z direction are mutually intersecting directions. More specifically, the X direction, Y direction, and Z direction intersect orthogonal with each other.

The magnetic memory device according to the present embodiment is provided on a semiconductor substrate (not shown) and includes a plurality of magnetoresistance effect elements 10, a plurality of electrodes 50, a plurality of wiring lines 60, and an insulating region 70.

The magnetoresistance effect elements 10 are arranged in the X direction and the Y direction, and each of the magnetoresistance effect elements 10 includes a main body portion 20, an upper structure portion 30, and a sidewall insulating layer 40. The magnetoresistance effect elements 10 of this embodiment are spin transfer torque (STT) type magnetic tunnel junction (MTJ) elements having perpendicular magnetization.

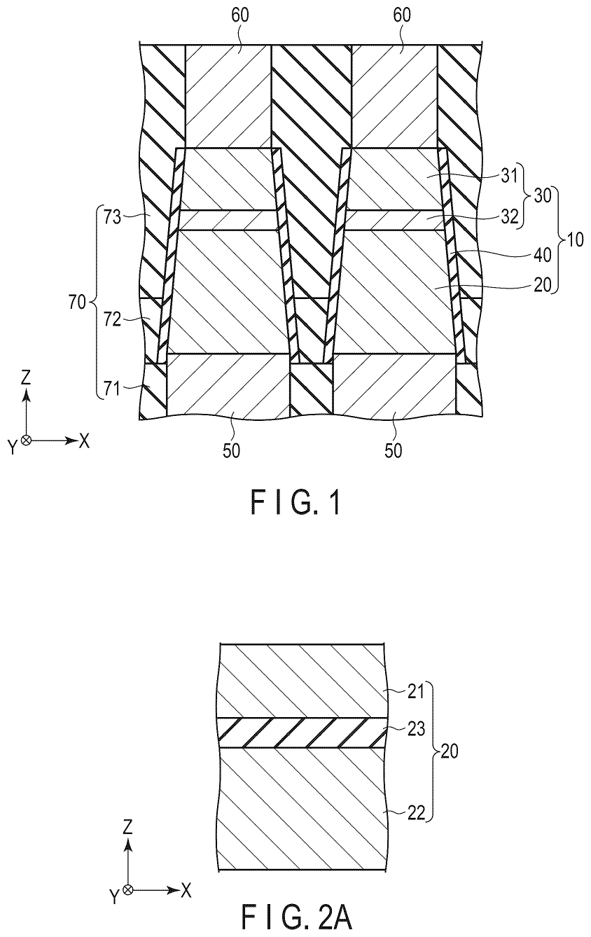

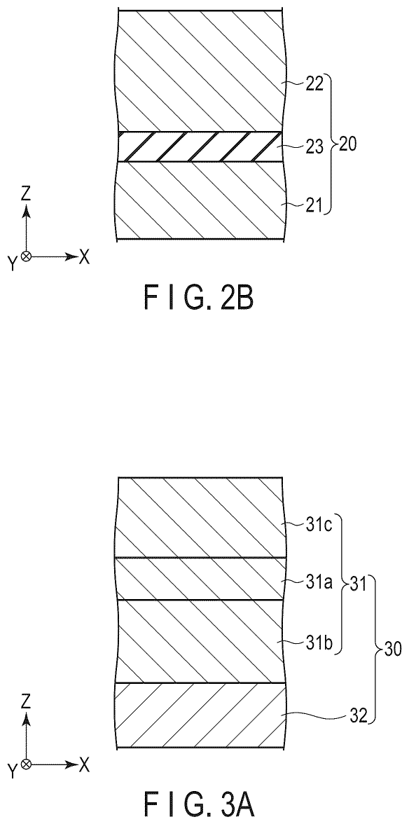

FIGS. 2A and 2B are cross-sectional views schematically showing a configuration of the main body portion 20 of the magnetoresistance effect element 10.

The main body portion 20 includes a storage layer (first magnetic layer) 21, a reference layer (second magnetic layer) 22, and a tunnel barrier layer (non-magnetic layer) 23, and has a structure in which the storage layer 21, the reference layer 22, and the tunnel barrier layer 23 are stacked along the Z direction.

FIG. 2A shows a top-free type structure in which the storage layer 21 is located on the upper layer side of the reference layer, and FIG. 2B shows a bottom-free type structure in which the storage layer 21 is located on the lower layer side of the reference layer. In this embodiment, either one of the structures may be employed.

The storage layer 21 is a ferromagnetic layer having a variable magnetization direction. The storage layer 21 is formed, for example, from a CoFeB layer containing cobalt (Co), iron (Fe), and boron (B). The term “variable magnetization direction” means that the magnetization direction changes for a predetermined write current.

The reference layer 22 is a ferromagnetic layer having a fixed magnetization direction. The reference layer 22 is formed, for example, by a CoFeB layer containing cobalt (Co), iron (Fe), and boron (B), and a superlattice layer of cobalt (Co) and platinum (Pt). The term “fixed magnetization direction” means that the magnetization direction does not changes for a predetermined write current.

The tunnel barrier layer 23 is an insulating layer provided between the storage layer 21 and the reference layer 22. The tunnel barrier layer 23 is formed, for example, from an MgO layer containing magnesium (Mg) and oxygen (O).

When the magnetization direction of the storage layer 21 is parallel to the magnetization direction of the reference layer 22, the main body portion 20 of the magnetoresistance effect element 10 is in a low-resistance state with relatively low resistance. When the magnetization direction of the storage layer 21 is antiparallel to the magnetization direction of the reference layer 22, the main body portion 20 of the magnetoresistance effect element 10 is in a high-resistance state with relatively high resistance. With this configuration, the magnetoresistance effect element 10 can store binary data depending on the resistance state.

The upper structure portion 30 is stacked on the main body portion 20, and includes a hard mask portion (first structure portion) 31 and a cap layer portion (second structure portion) 32 provided between the main body portion 20 and the hard mask portion 31. The upper structure portion 30 is electrically conductive and also functions as the top electrode of the magnetoresistance effect element 10.

The sidewall insulating layer 40 is provided on the side wall of the main body portion 20 and the side wall of the upper structure portion 30. More specifically, the sidewall insulating layer 40 is provided along all the side wall of the main body portion 20 and all the side wall of the upper structure portion 30, and has a function of protecting the main body portion 20 and the upper structure portion 30.

The sidewall insulating layer 40 contains an oxide containing a predetermined element and oxygen, and the bond dissociation energy between the predetermined elements and oxygen is 500 kJ/mol or more. The predetermined element preferably be selected from hafnium (Hf), aluminum (Al), scandium (Sc), gadolinium (Gd), tantalum (Ta), yttrium (Y), and boron (B). Among these elements, aluminum has the lowest bond dissociation energy with oxygen, and to be more specific, the bond dissociation energy between aluminum and oxygen is 501.9 kJ/mol.

Each of the plurality of electrodes 50 functions as a bottom electrode of the magnetoresistance effect element 10. When a selector (a two-terminal switching element) is provided on the lower layer side of the magnetoresistance effect element 10 for selecting the magnetoresistance effect element 10, the electrode 50 functions as an upper electrode of the selector as well.

Each of the plurality of wiring lines 60 extends along the Y direction and is connected to the upper structure portions 30 of the magnetoresistance effect elements 10 arranged along the Y direction.

The insulating region 70 is provided around each of the magnetoresistance effect elements 10, the electrodes 50, and the wiring lines 60, and includes insulating layers 71, 72, and 73. The insulating layers 71, 72, and 73 are formed from a material different from that of the sidewall insulating layer 40. For example, the insulating layers 71, 72, and 73 are formed from silicon oxide.

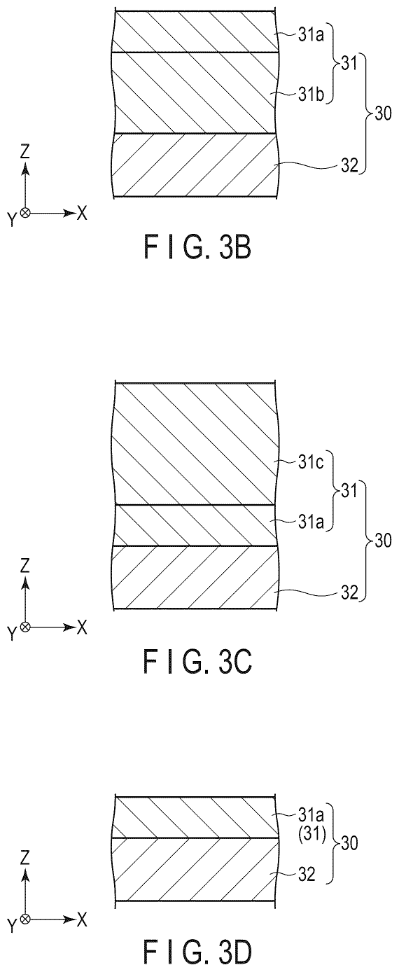

FIGS. 3A, 3B, 3C, and 3D are cross-sectional views schematically showing the first, second, third, and fourth specific examples of the upper structure portion 30, respectively.

As shown in FIGS. 3A, 3B, 3C, and 3D, the upper structure portion 30 includes a hard mask portion 31 and a cap layer portion 32.

In the first specific example shown in FIG. 3A, the hard mask portion 31 includes a predetermined material layer portion 31a, a lower material layer portion 31b provided on the lower layer side of the predetermined material layer portion 31a, and an upper material layer portion 31c provided on the upper layer side of the predetermined material layer portion 31a. In other words, the predetermined material layer portion 31a is provided between the lower material layer portion 31b and the upper material layer portion 31c.

The predetermined material layer portion 31a contains a conductive predetermined material containing an element selected from platinum (Pt), cobalt (Co), iridium (Ir), manganese (Mn), nickel (Ni), gold (Au), tantalum (Ta), and ruthenium (Ru). More specifically, the predetermined material layer portion 31a is formed solely from the above-listed predetermined material.

The lower material layer portion 31b and the upper material layer portion 31c each contain a conductive material different from the above-described predetermined material. The lower material layer portion 31b and the upper material layer portion 31c may be formed from different materials, but are usually formed from the same material. The lower material layer portion 31b and the upper material layer portion 31c are each formed from a material containing an element selected from tungsten (W) and titanium (Ti). In this embodiment, the lower material layer portion 31b and the upper material layer portion 31c are each formed from a tungsten (W) layer or a titanium nitride (TiN) layer.

The lower material layer portion 31b and the upper material layer portion 31c are the main portions of the hard mask portion 31 and are formed from a conventional hard mask material such as listed above. The predetermined material layer portion 31a is an additional portion of the hard mask portion 31 and is formed from a predetermined material having such a high etching resistance that the progression of etching is suppressed by the predetermined material layer portion 31a when the upper material layer portion 31c is excessively etched. More specifically, the predetermined material has a higher etching resistance to etching processes such as reactive ion etching (RIE) and ion beam etching (IBE) than those of the materials of the lower material layer portion 31b and the upper material layer portion 31c.

The cap layer portion 32 includes a conductive material different from the predetermined material, the material of the lower material layer portion 31b, and the material of the upper material layer portion 31c. Specifically, the material of the cap layer portion 32 contains an element selected from ruthenium (Ru) and hafnium (Hf). More specifically, the cap layer portion 32 is formed from a ruthenium (Ru) layer or a hafnium (Hf) layer.

In the second specific example shown in FIG. 3B, the hard mask portion 31 includes the predetermined material layer portion 31a and the lower material layer portion 31b, but does not include the upper material layer portion 31c. Other basic items are similar to those described in the first specific example.

The configuration of this specific example is obtained, for example, in the case where, when forming a configuration similar to that of the first specific example, the entire upper material layer portion 31c is removed by etching to expose the predetermined material layer portion 31a.

In the third specific example shown in FIG. 3C, the hard mask portion 31 includes the predetermined material layer portion 31a and the upper material layer portion 31c provided on the upper side of the predetermined material layer portion 31a. That is, in this specific example, the lower material layer portion 31b is not provided, and the predetermined material layer portion 31a is directly provided on the cap layer 32. Further, in this specific example, the predetermined material layer portion 31a contains a conductive predetermined material containing an element selected from platinum (Pt), cobalt (Co), iridium (Ir), manganese (Mn), nickel (Ni), gold (Au), and tantalum (Ta). More specifically, the predetermined material layer portion 31a is formed solely from the above-described predetermined material. Other basic items are similar to those described in the first specific example.

In the fourth specific example shown in FIG. 3D, the hard mask portion 31 includes only the predetermined material layer portion 31a and does not include the lower material layer portion 31b and the upper material layer portion 31c. Further, in this specific example as well, the predetermined material of the predetermined material layer portion 31a is the same as the predetermined material described in the third specific example. Other basic items are similar to those described in the first specific example.

The configuration of this specific example is obtained, for example, in the case where, when forming a configuration similar to that of the third specific example, the entire upper material layer portion 31c is removed by etching to expose the predetermined material layer portion 31a.

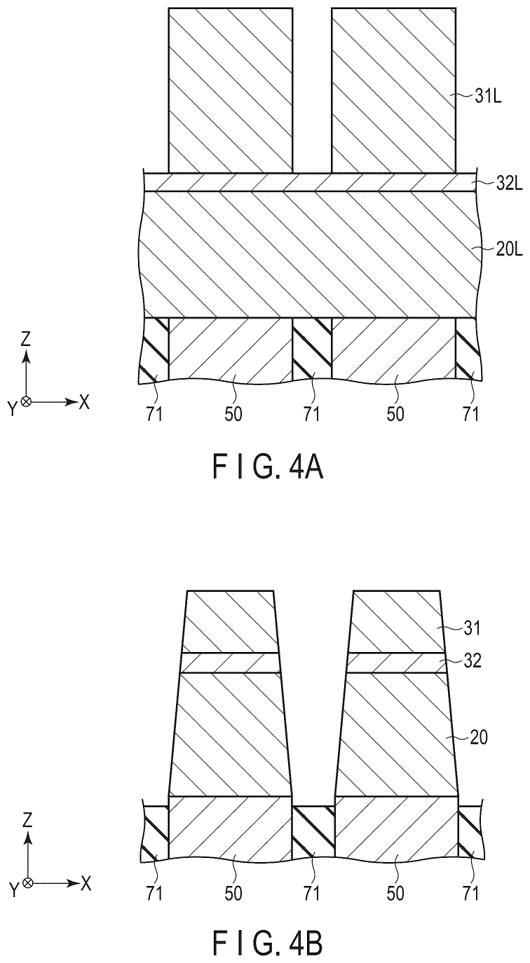

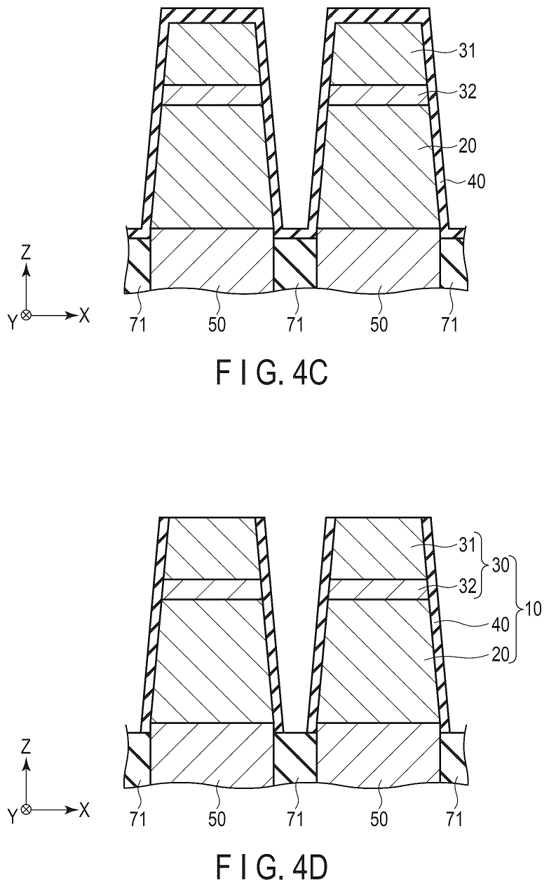

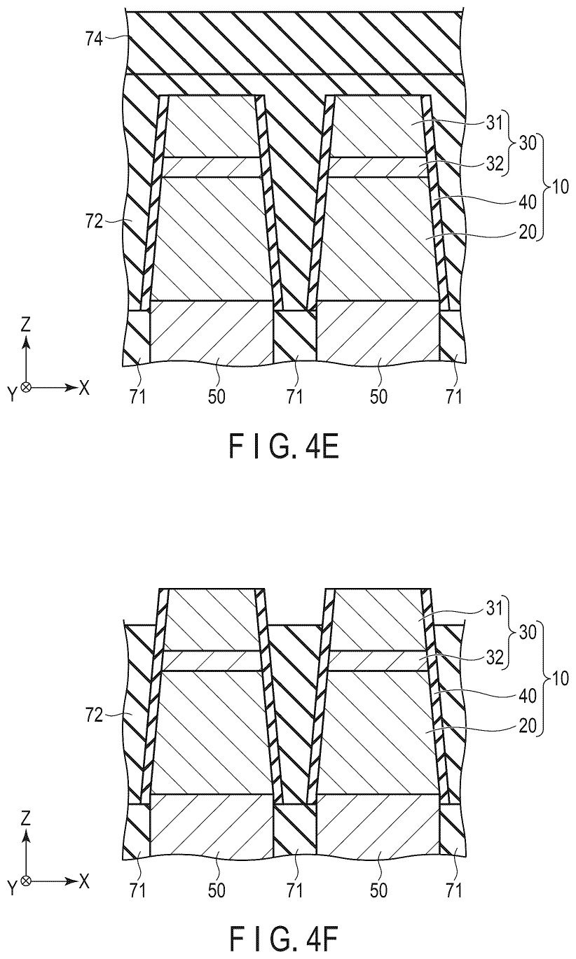

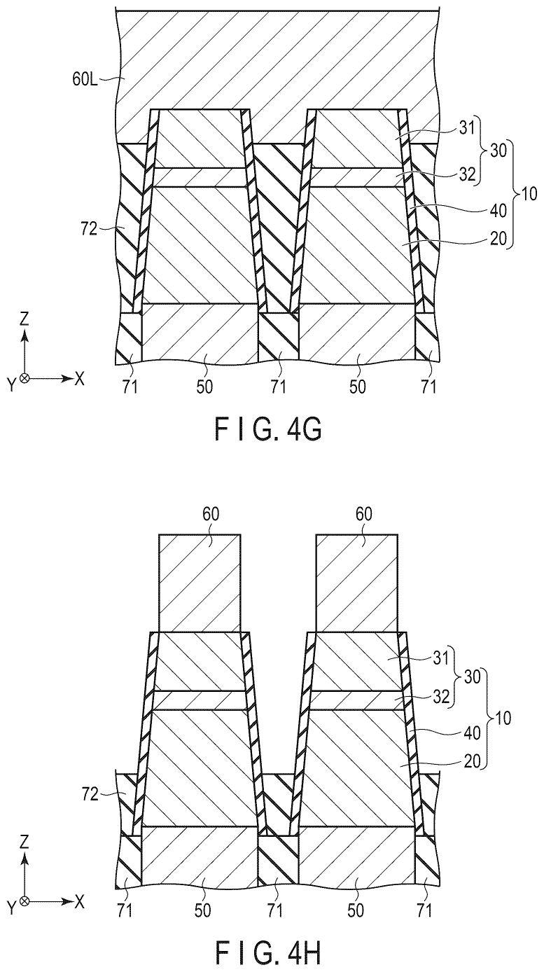

Next, a method of manufacturing the magnetic memory device according to this embodiment will be described with reference to the cross-sectional views shown in FIGS. 4A to 4H.

First, as shown in FIG. 4A, a main body portion layer 20L of the magnetoresistance effect element is formed on the configuration including the electrodes 50 and the insulating layers 71, and thereafter, a cap layer 32L is formed on the main body portion layer 20L. Further, a pattern of the hard mask layer 31L is formed on the cap layer 32L.

Next, as shown in FIG. 4B, the main body portion layer 20L and the cap layer 32L are etched using the pattern of the hard mask layer 31L as a mask by IBE. During this etching process, the hard mask layer 31L is also etched, and therefore the height of the hard mask layer 31L is reduced. In this way, the patterns of the main body portion 20 of the magnetoresistance effect element 10, the hard mask portion 31, and the cap layer portion 32 are formed into a tapered shape.

Subsequently, as shown in FIG. 4C, a sidewall insulating layer 40 is formed so as to cover the configuration obtained in the processing step of FIG. 4B.

Then, as shown in FIG. 4D, an etch-back process is performed on the sidewall insulating layer 40, and thus the sidewall insulating layer 40 remains only on the side surface of the main body portion 20 and the side surface of the upper structure portion 30.

Next, as shown in FIG. 4E, an insulating layer (passivation layer) 72 is formed so as to cover the configuration obtained in the processing step of FIG. 4D, and an insulating layer 74 is formed on the insulating layer 72.

Subsequently, as shown in FIG. 4F, the insulating layers 72 and 74 are etched using RIE to expose the upper surface of the hard mask portion 31.

Then, as shown in FIG. 4G, a wiring layer 60L is formed on the configuration obtained in the processing step of FIG. 4F.

Subsequently, as shown in FIG. 4H, the wiring layer 60L is etched using RIE to form the pattern for the wiring lines 60. During this etching process, the insulating layer 72 is also etched, and therefore the height of the insulating layer 72 is reduced.

Thereafter, the insulating layer 73 is formed, and thus a magnetic memory device having such a configuration as shown in FIG. 1 can be obtained.

As described above, in this embodiment, the sidewall insulating layer 40 is formed from an oxide containing a predetermined element and oxygen, and the bond dissociation energy between the predetermined element and oxygen is 500 kJ/mol or more. With this configuration, it exhibits high etching resistance against etching such as RIE. With the sidewall insulating layer 40 thus formed using such an oxide material, it is possible to effectively protect the side surface of the main body portion 20 of the magnetoresistance effect element 10 and the side surface of the upper structure portion 30 during the etching process by the sidewall insulating layer 40.

Further, in this embodiment, with the predetermined material layer portion 31a formed from the above-described predetermined material provided in the hard mask portion 31, it is possible to prevent the hard mask portion 31 from being excessively etched, thereby preventing the main body portion 20 of the magnetoresistance effect element 10 from being exposed.

Therefore, according to this embodiment, it is possible to effectively prevent the main body portion 20 of the magnetoresistance effect element 10 from being exposed by the sidewall insulating layer 40 and the predetermined material layer portion 31a of the hard mask portion 31.

For example, in the case where such a configuration of this embodiment as described above is not applied, the hard mask portion 31 may be excessively etched during the etching process shown in FIG. 4B, causing the main body portion 20 to be exposed. Furthermore, during the etching process shown in FIG. 4F, the thickness of the hard mask portion 31 may become excessively thin, possibly exposing the main body portion 20. Moreover, during the etching process shown in FIG. 4H, if the pattern of the wiring lines 60 is misaligned with the pattern of the main body portion 20, the main body portion 20 may be exposed.

By employing the configuration of this embodiment, the above-described problems can be prevented. That is, the adverse effects on the main body portion of the magnetoresistance effect element due to the above-described problems can be suppressed. As a result, it is possible to improve the yield of the magnetic memory device.

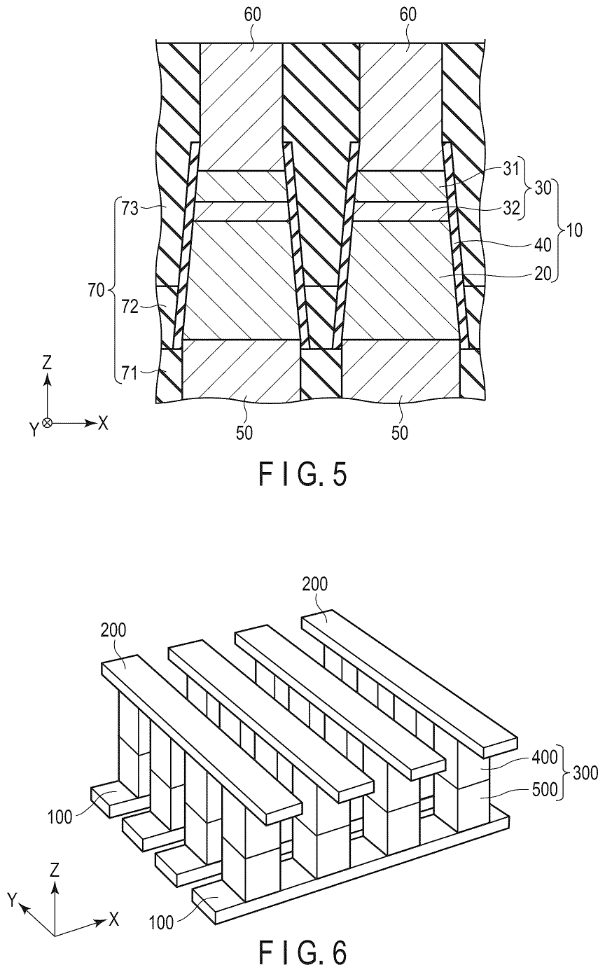

FIG. 5 is a cross-sectional view schematically showing the configuration of a modified example of the magnetic memory device according to this embodiment.

In this embodiment, the sidewall insulating layer 40 includes a portion that is leveled higher than the upper surface of the upper structure portion 30. In other words, the position of the upper end of the sidewall insulating layer 40 is higher than the position of the upper surface of the upper structure portion 30. Here, note that, for example, there may be such a case where, while etching the insulating layers 72 and 74 in the processing step shown in FIG. 4F to expose the upper surface of the hard mask portion 31, the hard mask portion 31 is excessively etched. In such a case, since the sidewall insulating layer 40 has high etching resistance, the position of the upper end of the sidewall insulating layer 40 becomes higher than the position of the upper surface of the upper structure portion 30.

In this modified example as well, the basic configuration is similar to that of the embodiment described above, and advantageous effects similar to those of the embodiment described above can be obtained.

FIG. 6 is a perspective view schematically showing a configuration of an application example of this embodiment.

The magnetic memory device shown in FIG. 6 comprises a plurality of lower wiring lines 100, a plurality of upper wiring lines 200, and a plurality of memory cells 300 provided between the lower wiring lines 100 and the upper wiring lines 200. Each of the memory cells 300 has a configuration in which a magnetoresistance effect element 400 and a selector 500 are stacked in the Z direction.

The magnetoresistance effect elements 400 and the upper wiring lines 200 correspond to the magnetoresistance effect elements 10 and the wiring lines 60 of the embodiment described above. Further, one of the groups of the lower wiring lines 100 and upper wiring lines 200 corresponds to word lines, and the other group of the lower wiring lines 100 and upper wiring lines 200 corresponds to bit lines.

The selector 500 is a two-terminal switching element that has the characteristic of changing from an off state to an on state when the voltage applied between the two terminals becomes equal to a threshold voltage or greater. Therefore, when a voltage is applied between the lower wiring line 100 and the upper wiring line 200, and the voltage applied between the two terminals of the selector 500 reaches or exceeds the threshold voltage, the selector 500 is set in an on state, thus making it possible to perform a write or read operation on the magnetoresistance effect element 400 connected in series with the selector 500.

By applying the magnetic memory device described above to a device such as that shown in FIG. 6, it is possible to obtain an excellent magnetic memory device with high-yield.

While certain embodiments have been described, these embodiments have been presented by way of example only, and are not intended to limit the scope of the inventions. Indeed, the novel devices and methods described herein may be embodied in a variety of other forms; furthermore, various omissions, substitutions and changes in the form of the embodiments described herein may be made without departing from the spirit of the inventions. The accompanying claims and their equivalents are intended to cover such forms or modification as would fall within the scope and spirit of the inventions.

What is claimed is

1. A magnetic memory device comprising:
a main body portion of a magnetoresistance effect element, including a first magnetic layer, a second magnetic layer, and a non-magnetic layer provided between the first magnetic layer and the second magnetic layer;
an upper structure portion of the magnetoresistance effect element, stacked on the main body portion; and
a sidewall insulating layer of the magnetic resistance effect element, provided on a side wall of the main body portion and on a side wall of the upper structure portion, containing an oxide containing a predetermined element and oxygen, and having a bond dissociation energy between the predetermined element and oxygen of 500 kJ/mol or more,
wherein
the upper structure portion includes a first structure portion including:
a predetermined material layer portion containing a predetermined material that contains an element selected from platinum (Pt), cobalt (Co), iridium (Ir), manganese (Mn), nickel (Ni), gold (Au), tantalum (Ta), and ruthenium (Ru), and
a lower material layer portion provided on a lower layer side of the predetermined material layer portion and containing a material different from the predetermined material.

2. The device of claim 1, wherein
the first structure portion further includes an upper material layer portion provided on an upper layer side of the predetermined material layer portion and containing a material different from the predetermined material.

3. The device of claim 2, wherein
the material contained in the lower material layer portion and the material contained in the upper material layer portion are same as each other.

4. The device of claim 2, wherein
the material contained in the upper material layer portion contains an element selected from tungsten (W) and titanium (Ti).

5. The device of claim 1, wherein
the material contained in the lower material layer portion contains an element selected from tungsten (W) and titanium (Ti).

6. The device of claim 1, wherein
the upper structure portion further includes a second structure portion provided between the main body portion and the first structure portion and containing a material different from the predetermined material.

7. The device of claim 6, wherein
the material contained in the second structure portion contains an element selected from ruthenium (Ru) and hafnium (Hf).

8. The device of claim 1, wherein
the predetermined element is selected from hafnium (Hf), aluminum (Al), scandium (Sc), gadolinium (Gd), tantalum (Ta), yttrium (Y), and boron (B).

9. The device of claim 1, wherein
the sidewall insulating layer includes a portion positioned higher than an upper surface of the upper structure portion.

10. A magnetic memory device comprising:
a main body portion of a magnetoresistance effect element, including a first magnetic layer, a second magnetic layer, and a non-magnetic layer provided between the first magnetic layer and the second magnetic layer;
an upper structure portion of the magnetoresistance effect element, stacked on the main body portion; and
a sidewall insulating layer of the magnetoresistance effect element, provided on a side wall of the main body portion and on a side wall of the upper structure portion, containing an oxide containing a predetermined element and oxygen, and having a bond dissociation energy between the predetermined element and oxygen of 500 kJ/mol or more,
wherein
the upper structure portion includes a first structure portion including a predetermined material layer portion containing a predetermined material that contains an element selected from platinum (Pt), cobalt (Co), iridium (Ir), manganese (Mn), nickel (Ni), gold (Au), and tantalum (Ta).

11. The device of claim 10, wherein
The first structure portion further includes a lower material layer portion provided on a lower layer side of the predetermined material layer portion and containing a material different from the predetermined material.

12. The device of claim 11, wherein
the material contained in the lower material layer portion contains an element selected from tungsten (W) and titanium (Ti).

13. The device of claim 10, wherein
the first structure portion further includes an upper material layer portion provided on an upper layer side of the predetermined material layer portion and containing a material different from the predetermined material.

14. The device of claim 13, wherein
the material contained in the upper material layer portion contains an element selected from tungsten (W) and titanium (Ti).

15. The device of claim 10, wherein
the upper structure portion further includes a second structure portion provided between the main body portion and the first structure portion and containing a material different from the predetermined material.

16. The device of claim 15, wherein
the material contained in the second structure portion contains an element selected from ruthenium (Ru) and hafnium (Hf).

17. The device of claim 10, wherein
the predetermined element is selected from hafnium (Hf), aluminum (Al), scandium (Sc), gadolinium (Gd), tantalum (Ta), yttrium (Y), and boron (B).

18. The device of claim 10, wherein
the sidewall insulating layer includes a portion positioned higher than an upper surface of the upper structure portion.
